(19) United States
(12) Patent Application Publication
(10) Pub. No.: US 2007/0139074 A1
(43) Pub. Date: Jun. 21, 2007

(54) Configurable circuits with microcontrollers

(75) Inventor: Frederic Reblewski, Paris (FR)

Correspondence Address: SCHWABE, WILLIAMSON & WYATT, P.C.;PACWEST CENTER, SUITE 1900, 1211 SW FIFTH AVENUE, PORTLAND, OR, 97204, US

(73) Assignee: M2000

(21) Appl. No.: 11/311,718

(22) Filed: Dec. 19, 2005

(51) Int. Cl. H03K 19/173

(52) U.S. Cl. 326/38

(57) ABSTRACT

Configurable circuits with microcontrollers are described herein. The microcontrollers may perform a variety of functions including the control of configurations of the configurable circuits.

### TECHNICAL FIELD

Embodiments of the present invention relate to the field of integrated circuits, more specifically, to configurable integrated circuits

### BACKGROUND

A configurable circuit is typically an integrated circuit that includes an array of configurable resources including a plurality of configurable functions (i.e., configurable function blocks) and a plurality of configurable interconnects that are coupled to the configurable functions. When employed, a configurable circuit is configured in a particular manner so that it can execute some application. The configuration of a configurable circuit will be based on configuration data that is typically provided to the configurable circuit from some external source. The configuration data to be supplied to the configurable circuit will usually include data for configuring the configurable functions and routing information for configuring the configurable interconnects.

An example of a configurable circuit is an integrated circuit that includes a Field Programmable Gate Array (FPGA) that can be configured on the field to execute any user application that remains below a certain level of complexity given by the size of the FPGA and its routing capacity. When used as part of a system, configurable circuits such as FPGA circuits are typically accompanied by nonvolatile memory (i.e., configuration memory) such as read-only memory (ROM) that can store the configuration data to be used to configure the configurable circuits.

There are at least two phases when such configurable circuits are powered up. First, the configurable circuit loads the configuration data from the configuration memory, and second, the configurable circuit is configured in accordance with the configuration data so that it can execute an application.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIG. 1 illustrates a system that includes a conventional configurable circuit;

FIG. 2 illustrates a configurable circuit with a microcontroller in accordance with various embodiments of the present invention; and

FIG. 3 illustrates another configurable circuit with a microcontroller in accordance with various embodiments of the present invention.

### DETAILED DESCRIPTION OF EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

The description may use perspective-based descriptions such as up/down, back/front, and top/bottom. Such descriptions are merely used to facilitate the discussion and are not intended to restrict the application of embodiments of the present invention.

For the purposes of the present invention, the phrase “A/B” means A or B. For the purposes of the present invention, the phrase “A and/or B” means “(A), (B), or (A and B).” For the purposes of the present invention, the phrase “at least one of A, B and C” means “(A), (B), (C), (A and B), (A and C), (B and C) or (A, B and C).” For the purposes of the present invention, the phrase “(A)B” means “(B) or (AB)” that is, A is an optional element.

The description may use the phrases “in various embodiments,” or “in some embodiments,” which may refer to one or more of the same or different embodiments. Furthermore, the terms “comprising,” “including,” “having,” and the like, as used with respect to embodiments of the present invention, are synonymous.

Embodiments of the present invention provide integrated circuits, such as configurable circuits, with microcontrollers. For the embodiments, the integrated circuits in addition to the microcontrollers may include arrays having a plurality of configurable functions coupled to a plurality of configurable interconnects. In some embodiments, the integrated circuits may be circuits that include FPGAs. The microcontrollers may be coupled to the arrays to execute a plurality of instructions to control configuration of the configurable functions and configurable interconnects, and storages may be coupled to the microcontrollers to store working data associated with the execution of the instructions.

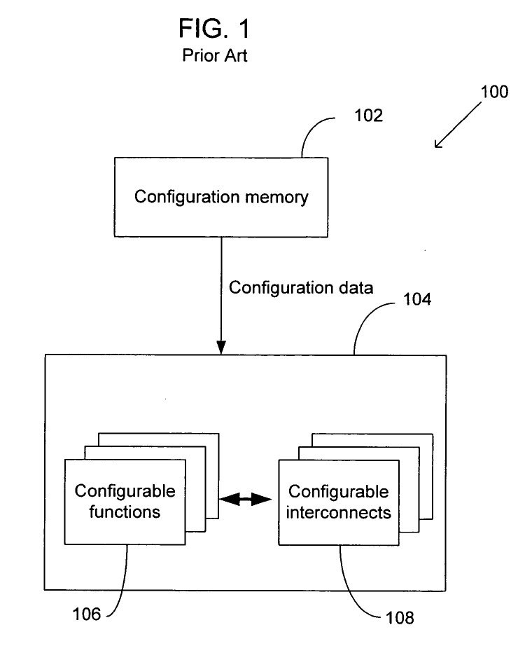

In order to appreciate various aspects of embodiments of the invention, a brief description of a conventional system that includes a conventional configurable circuit will be described first. FIG. 1 is a simplified depiction of a system 100 that includes a configuration memory 102, such as nonvolatile memory (e.g., ROM), and a conventional configurable circuit 104, coupled together as shown. In such a system 100, the configuration memory 102 provides configuration data to the conventional configurable circuit 104. The configurable circuit 104 includes an array comprising a plurality of configurable functions 106 and a plurality of configurable interconnects 108 coupled together as shown. The configurable functions 106 typically include programmable gates while the configurable interconnects typically include programmable network of wires and switches including for example, crossbar devices.

As depicted, such a system 100 may give rise to a number of issues that may prevent the configurable circuit 104 as well as the system 100 that the configurable circuit 104 is part of from performing optimally. For example, the configuration data provided to the configurable circuit 104, in some instances, may result in a configuration that may damage the configurable circuit 104. This may be as a result of, for example, the conflicts that may arise between several configurable drivers simultaneously configured to drive the same wire to conflicting values while the configurable circuit 104 was designed to be configured in such a way that no more than one driver would be active.

A second issue that may arise is that because the configuration data to be loaded onto the configurable circuit 104 must typically be in a finalized bit form that can be directly read by the configurable functions 106 and the configurable interconnects 108 to configure themselves, thus as integrated circuit technology continues to improve, with more and more configuration functions 106 and configurable interconnects 108 being included in a configurable circuit 104, the configuration memory 102 must typically be very large in order to store such data.

A third issue that may arise is when the configuration data to be provided to the configurable circuit 104 is somehow not suitable for properly configuring the configurable circuit 104. That is, in some instances, the configuration data provided by the configuration memory 102 may have been originally created for a particular configurable circuit having particular characteristics such as a particular array size and structure and/or for a configurable circuit having elements (e.g., configurable functions and configurable interconnects) with specific characteristics. For example, it is common for the manufacturer of the configurable circuit 104 to make several different versions of configurable circuits having different characteristics. Designers may then purchase these configurable circuits from the manufacturer to be, for example, included in a system and further provide the configuration data needed to configure the configurable circuits as well as the application to be executed on the configured circuits. Unfortunately, the configuration data provided by the designer may not be compatible with one or some of the different versions of the configurable circuits provided by the manufacturer.

A fourth issue that may arise with a conventional configurable circuit 104 is that they may not be able to work around faulty elements that may be present in the configurable circuit 104. That is, in the case whereby one or more of the configurable functions 106 and/or configurable interconnects 108 of the configurable circuit 104 is/are faulty, there may be no way for the configurable circuit 104 by itself to deal with such problems even if the configurable circuit 104 has redundant elements. These are just some of the issues that may be associated with a conventional configurable circuit such as the one depicted in FIG. 1.

In accordance with various embodiments, configurable integrated circuits with microcontrollers are provided. For the embodiments, the configurable integrated circuits may include arrays of configurable functions and configurable interconnects. The microcontrollers may be able to perform a variety of functions including control of the configurations of the configurable functions and configurable interconnects included in the configurable integrated circuits (herein “configurable circuits”). In some embodiments, the microcontrollers may ensure that the configurable circuits are not damaged as a result of configurations of the configurable circuits.

In some embodiments, the microcontroller may particularize the configuration data provided to the configurable circuits with respect to the specific elements present in the configurable circuits. This means that for these embodiments, the microcontrollers may adapt or particularize the configuration data that are received by the configurable circuits taking into account the specific characteristics of the configurable circuits including the type and size of the arrays included in the configurable circuits and/or the specific characteristics of their elements (e.g., configurable functions and configurable interconnects).

In some embodiments, the microcontrollers may further facilitate overcoming faulty elements that may be present in the configurable circuits by finalizing the routing information included in the configuration data that are loaded onto the configurable circuits, while taking into account the timing characteristics of the arrays to ensure the timings of the applications to be executed on the circuits are not violated. The microcontrollers may, in some embodiments, facilitate built-in self-test (BIST) before or after the configuration data are loaded. Other types of functions may further be executed by the microcontrollers in various other embodiments.

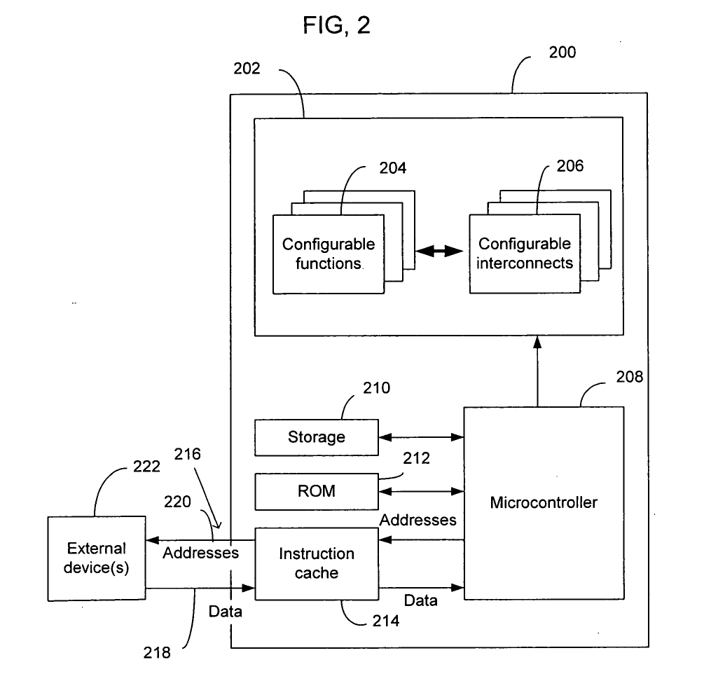

FIG. 2 depicts a configurable circuit with a microcontroller in accordance with some embodiments. For the embodiments, the configurable circuit 200 may include an array 202 including a plurality of configurable functions 204 and a plurality of configurable interconnects 206 coupled to the configurable functions 204, a microcontroller 208, a storage 210, a read-only memory (ROM) 212, and an instruction cache 214, coupled together as shown. The configurable circuit 200 may further include an input/output (I/O) interface 216 adapted to couple with one or more devices 222 external to the configurable circuit 200. The I/O interface 216 may further include at least a data port for an input data line 218, and an output address port for an address line 220.

In some embodiments, the external device(s) 222 may provide instructions and/or configuration data to the configurable circuit 200. The instructions provided by the external device(s) 222, when executed by the microcontroller 208, may facilitate the performance of various functions including, for example, configuration of the configurable circuit 200. The configuration data provided by the external device(s) 222 may be used at least in part to configure the configurable functions 204 and configurable interconnects 206.

Note that although the I/O interface 216 was previously described as having only a data port and an address port, the I/O interface 216 may further include other ports including one or more instruction or programming ports. Note further that in alternative embodiments, one or more of the components such as storage 210, ROM 212, and instruction cache 214 may be absent, while in other or the same embodiments, additional components may be included in the configurable circuit 200.

As previously alluded to, the configurable functions 204 and the configurable interconnects 206 may be configured based at least in part on configuration data supplied by the external device(s) 222. In some embodiments, the configuration data to be provided by the external device(s) 222 may be in a symbolic form not fully particularized to properly configure the configurable circuit 200 with respect to the specific elements of the configurable functions 204 and configurable interconnects 206. For these embodiments, the configuration data may be particularized using the microcontroller 208 as will be further discussed in greater detail below. In yet other embodiments, or the same embodiments, the external device(s) 222 may provide to the configurable circuit 200, instructions to facilitate configuration of the configurable circuit 200. In various embodiments, the external device(s) 222 may include nonvolatile memory such as ROM for storing the configuration data and/or instructions.

According to embodiments of the invention, the microcontroller 208 may execute a plurality of instructions to control the configuration of the configurable functions 204 and configurable interconnects 206. The instructions may be supplied by, in some embodiments, the external device(s) 222. Alternatively, the instructions or a subset of the instructions may be stored in an internal memory such as the ROM 212. The microcontroller 208 may further receive configuration data that is to be used, at least in part, to configure the elements of the array 202, and to process the configuration data based on the instructions. The instructions may further facilitate the microcontroller 208 to perform various other functions such as determining whether a configuration will damage the configurable circuit 200 or to particularize the configuration data so as to account for the specific characteristics of the array 202 and/or its elements as will be discussed below.

In various embodiments, the microcontroller 208 may access the external device(s) 222 in order to retrieve the instructions. For these embodiments, the external device(s) 222 may include nonvolatile memory such as a ROM as previously described, and the accessing of the external device(s) 222 may be achieved by providing addresses to the external device(s) 222. In some embodiments, and although not depicted, the integrated circuit 200 may include a circuit coupled to the instruction cache 214 and the I/O interface 216 to successively fetch subsets of the instructions to be executed by the microcontroller 208 into the instruction cache 214 from the external device[s] 222 that may be coupled to the I/O interface 216.

The instructions to be executed by the microcontroller 208 may perform various functions as previously alluded to. For example, in some embodiments, the instructions when executed on the microcontroller 208 may determine whether a configuration of the configurable functions 204 and configurable interconnects 206 is harmless. A configuration may be harmful to the configurable circuit 200 in some instances because of the particular structure of the configurable circuit 200 and the conflicts that may arise between drivers when the configurable circuit 200 is configured in a particular manner.

In some embodiments, the instructions may be designed to, when executed on the microcontroller 208, particularize the configuration data that is to be used to configure the configurable circuit 200. For these embodiments, configuration data that are provided by, for example, the external device(s) 222, may be in a symbolic form that is not fully particularized with respect to the specific element of the configurable functions 204 and configurable interconnects 206. The instructions, when executed by the microcontroller 208, may process the received configuration data and generate in response, configuration data that are fully particularized with respect to specific elements of the configurable functions 204 and configurable interconnects 206 to be configured. That is, by transforming or particularizing the received configuration data, the resulting configuration data may specifically accommodate for the specific characteristics of the configurable circuit array and/or its elements.

In some embodiments, the instructions may be designed to, when executed using the microcontroller 208, determine the presence of any faulty elements in the array 202, and if any faulty elements are found, to transparently effectuate a desired configuration of the array 202 using available redundant configurable functions to substitute for the faulty configurable functions and/or using available redundant configurable interconnects to substitute for faulty configurable interconnects. Based on the instructions, the microcontroller 208 may transparently adapt the received configuration data to enable redundant one(s) of the configurable resources and/or configurable interconnects to be employed to substitute for the faulty one(s).

As depicted, a storage 210 may be coupled to the microcontroller 208, the storage 210 being adapted to store working data that may be associated with the execution of instructions by the microcontroller 208. In some embodiments, the working data may be temporary data generated and/or processed by the microcontroller 208 when it executes its various functions. An instruction cache 214 may be further coupled to the microcontroller 208 to cache at least a subset of the instructions to be received from the external device(s) 222. In some embodiments, the presence of the instruction cache 214 may eliminate the need for a high bandwidth connection from the external device(s) 222.

In various embodiments, the ROM 212 may store instructions and/or data that facilitate the microcontroller 208 in performing the various functions previously described or other functions. For example, in some embodiments, the ROM 212 may store all or some of the instructions and/or data to be used to control the configuration of the array 202. These may include instructions and/or generic data to determine whether a configuration of the integrated circuit 200 is harmless to the integrated circuit 200. In some embodiments, the data stored in the ROM 212 may be circuit data that specify or describe the characteristics of the array 202 and its elements. These may include, for example, the size and structure of the array 202 and the individual characteristics of the configurable functions 204 and configuration interconnects 206. In some embodiments, the ROM 212 may store data (and/or instructions) to allow the microcontroller 208 to boot up on its internal safe code and to jump to an external code once some verification has been done, such as a checksum, to ensure that the instructions or data received from the external device(s) 222 have not been damaged.

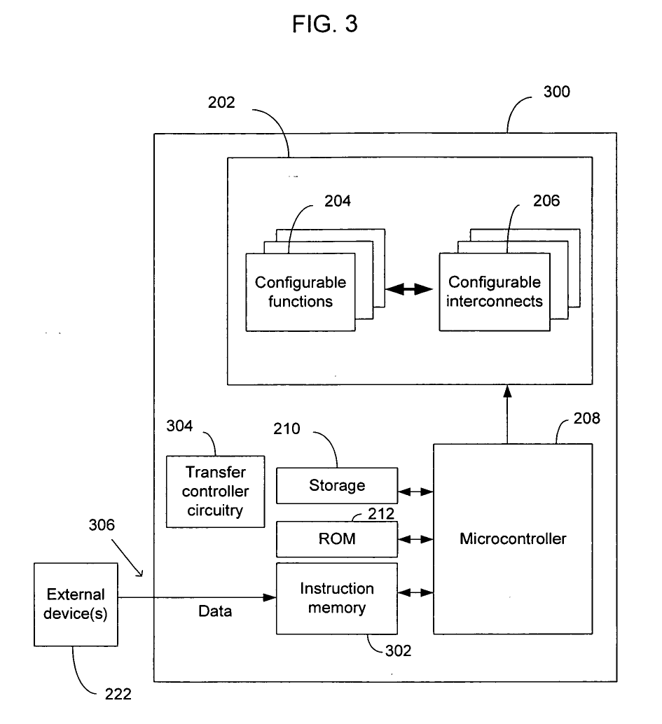

FIG. 3 depicts a configurable circuit with a microcontroller in accordance with various embodiments. For the embodiments, and similar to the configurable circuit 200 of FIG. 2, the configurable circuit 300 may include an array 202 including a plurality of configurable functions 204 and a plurality of configurable interconnects 206, a microcontroller 208, a storage 210, and a read-only memory (ROM) 212, coupled together as shown. The configurable circuit 300 may further include an input/output (I/O) interface 306 adapted to couple with device(s) 222 external to the configurable circuit 300. All of these components may perform similar roles as described for the embodiments of FIG. 2. Unlike the configurable circuit 200 depicted in FIG. 2, however, the configurable circuit 300 may further include a transfer controller circuitry 304, an instruction memory 302 instead of an instruction cache 214, and no output address line going through the I/O interface 306.

In various embodiments, the configurable circuit 300 may be particularly suitable when the external device(s) 222 provides, for example, the data and/or the instructions in a bit stream that cannot be controlled by the microcontroller 208 by means of addresses. For these embodiments, the transfer controller circuitry 304 may be capable of copying data and/or instructions received from the external device(s) 222 to the instruction memory 302 so that the data (or instructions) from the external device(s) 222 can be processed in several steps, one block of data at a time, making it unnecessary to provide an internal memory that is large enough to hold all of the data and/or instructions to be provided by the external device(s) 222. In some embodiments, the ROM 212 may not be present and the instruction memory 302 may be directly loaded from the external device(s) 222 before the microcontroller executes its first instruction.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

1. An integrated circuit, comprising:
an array including a plurality of configurable functions and a plurality of configurable interconnects coupled to the configurable functions; and
a microcontroller coupled to the array to execute a plurality of instructions to control configuration of the configurable functions and configurable interconnects.

2. The integrated circuit of claim 1, wherein the integrated circuit further comprises an input/output (I/O) interface for coupling an external device having the instructions to the integrated circuit, and the microcontroller adapted to access the external device to retrieve the instructions.

3. The integrated circuit of claim 1 further comprising an instruction cache coupled to the microcontroller to cache at least a subset of the instructions.

4. The integrated circuit of claim 3, wherein the integrated circuit further comprises an input/output (I/O) interface for coupling the integrated circuit to a device external to the integrated circuit, and a circuit coupled to the instruction cache and the I/O interface to successively fetch subsets of said instructions into said instruction cache, from the external device coupled to the I/O interface.

5. The integrated circuit of claim 1, further comprising a read-only-memory coupled to the microcontroller, the read-only memory having stored therein said instructions.

6. The integrated circuit of claim 1, further comprising a read-only-memory coupled to the microcontroller, the read-only memory having data associated with said controlling of configuration.

7. The integrated circuit of claim 6, wherein said data comprises generic data for determining whether a configuration is harmless to the integrated circuit.

8. The integrated circuit of claim 6, wherein said data comprises circuit data describing characteristics of the integrated circuit.

9. The integrated circuit of claim 5, wherein the instructions are designed to determine whether a configuration is harmful to the integrated circuit.

10. The integrated circuit of claim 1, wherein the instructions are designed to process received configuration data that specify a configuration of the configurable functions and configurable interconnects in a symbolic form, not fully particularized, and to generate in response, configuration data that are fully particularized with respect to specific elements of the configurable functions and configurable interconnects to be configured.

11. The integrated circuit of claim 1, wherein the instructions are designed to determine presence of faulty elements, if any, within the configurable function and configurable interconnects, and to transparently effectuate a desired configuration using available redundant configurable functions to substitute for determined faulty ones of the configurable functions and/or using available redundant configurable interconnects to substitute for determined faulty ones of the configurable interconnects.

12. A method, comprising:
receiving by a configurable integrated circuit configuration data to configure configurable resources on the integrated circuit; and
determining by a microcontroller of the configurable integrated circuit whether the configuration specified by the configuration data is harmful to the integrated circuit.

13. A method, comprising:
receiving by a configurable integrated circuit configuration data to configure configurable resources on the integrated circuit, the configuration data being in symbolic form and not fully particularized with respect to specific elements of the configurable resources to be configured; and
processing the configuration data by a microcontroller of the configurable integrated circuit to transform the configuration data to be fully particularized with respect to specific elements of the configurable resources to be configured.

14. A method, comprising:
receiving by a configurable integrated circuit configuration data to configure configurable resources on the integrated circuit; and
transparently adapting the configuration data by a microcontroller of the configurable integrated circuit to enable redundant one(s) of the configurable resources to be employed to substitute for faulty one(s) of the configurable resources.

15. The integrated circuit of claim 1, further comprising a storage coupled to the microcontroller to store working data associated with said execution of instructions
